(19) United States
(12) Patent Application Publication
(10) Pub. No.: US 2012/0132864 A1
(43) Pub. Date: May 31, 2012

(54) CARBON NANOFIBER/CARBON NANOCOIL - COATED SUBSTRATE AND NANOCOMPOSITES

(76) Inventors: Kamal Krishna KAR, Kanpur (IN); Ariful Rahman, Kanpur (IN)

(21) Appl. No.: 13/375,730

(22) PCT Filed: Nov. 9, 2010
(86) PCT No.: PCT/IB2010/055080

§ 371 Date: Dec. 1, 2011

(30) Foreign Application Priority Data
Sep. 23, 2010 (IN) 2272/DEL/2010

(51) Int. Cl. C08K 3/04; H01B 1/24; C08K 3/40; C23C 16/00; B82Y 99/00

(52) U.S. Cl. 252/511; 428/370; 524/495; 524/494; 427/249.3; 977/762

(57) ABSTRACT

A composition includes a substrate and a carbon filament where the carbon filament has a first end in contact with the substrate and a second end that is distal to the substrate. The carbon filament may be a carbon nanofiber or carbon nanocoil. The substrate may be a glass fiber and the carbon filament may be radially attached to the glass fiber.

### FIELD

The technology is generally related to carbon coated substrates and nanocomposites.

### BACKGROUND

Glass fiber is known to impart lightness, strength, corrosion resistivity, electrical conductivity, thermal resistivity, dimensional stability, and chemical stability to materials. Because of such properties it is widely used as an advanced material in aerospace, building, civil engineering, transportation and shipbuilding. Despite these properties its mechanical performance, especially modulus, is poor when compared to carbon fiber (Table 1).

Carbon nanotubes (CNTs), nanofibers (CNFs), and carbon nanocoils (CNCs) collectively referred to herein as carbon filaments, have outstanding physical properties from a strength perspective (e.g. A Young's modulus ˜1.5 TPa and a tensile strength ˜100 GPa). CNTs have been incorporated in various matrices as small, discontinuous carbon filament segments. The conventional carbon fiber, which is micron sized in diameter, is fashioned into carbon fabrics. Typically, the fabrics are shaped in a pre-form and then a liquid matrix material is added under pressure to form a carbon fiber reinforced-matrix composite. However, if the CNTs are added to the liquid matrix material, even at low concentration, they tend to have a thickening effect, which makes thorough mixing all but impossible. Dispersion of CNTs/CNFs/CNCs into a matrix is a critical processing parameter for controlling the properties, however, they typically clump or agglomerate with other carbonaceous materials, which introduces defect sites that initiate failure. Thus, the incorporation of CNTs/CNFs/CNCs into polymer matrices remains problematic.

### SUMMARY

In one aspect, a composition is provided that includes a substrate and a carbon filament, where the carbon filament has a first end in contact with the substrate and a second end that is distal to the substrate. In some embodiments, the carbon filament is a carbon nanofiber or carbon nanocoil. In some embodiments, the carbon filament is radially attached to the glass fiber. In some embodiments of the composition, the carbon nanofiber/nanocoil is from 20 nm to 200 nm in width and from 0.5 μm to 10 μm long.

In some embodiments, the composition also includes a polymer, where the composition is a carbon fiber-polymer composite or carbon nanocoil-polymer composite. In some embodiments, the polymer is a thermoset polymer.

In some embodiments, the substrate is a metal oxide. In some embodiments, the substrate is a glass fiber. In some embodiments, the glass of the glass fiber is A-glass, E-glass, C-glass, D-glass, E-CR-glass, boron-containing E-glass, boron-free E-glass, R-glass, S-glass, T-glass, Te-glass, silica/quartz glass, low K glass, or hollow glass. In other embodiments, the glass fiber has a diameter of from 2 μm to 20 μm. In some embodiments, the glass fiber is a discontinuous mono-filament, a continuous mono-filament, a continuous flat multi-filament, a continuous twisted multi-filament, or a continuous textured multi-filament. In other embodiments, a plurality of the glass fibers are woven into a glass fabric. In such other embodiments, the glass fabric may include a weave that is a plain weave, basket weave, twill, 4-end satin, 5-end satin, 8-end satin, leno, mock leno, random fibers; braided yarn, orthogonal, cylindrical weave, or multi-directional weave.

In another aspect, a process is provided including coating a catalyst on the surface of a substrate to form a catalyst-coated substrate and exposing the catalyst-coated substrate to a carbon source gas at a temperature and a time sufficient to decompose the carbon source gas and deposit carbon on the surface of the catalyst-coated substrate as carbon nanofibers or carbon nanocoils. In such embodiments, the catalyst includes Ni, Ru, Rh, Pd, Ir, Pt, Cr, Mo, or W. In some embodiments, the catalyst includes a first metal that is Ni, Ru, Rh, Pd, Ir, or Pt, and a second metal that is Cr, Mo, or W. In some such embodiments, the second metal is Cr. In other embodiments, a ratio of the first metal to the second metal is 2:1 or greater. In other embodiments, the temperature is from 400° C. to 900° C. In some embodiments, the time is from 1 minute to 0.5 hours. In some embodiments, the exposing is carried out under an inert atmosphere. In yet other embodiments, the carbon source gas is CH₄, C₂H₆, C₃H₈, CO₂, ethylene, or acetylene. In some such embodiments, the carbon source gas also includes a reducing gas. In some embodiments, the reducing gas is Cl₂ or H₂.

In some embodiments, the coating includes dip-coating the substrate in a solution comprising the catalyst. In some embodiments, the catalyst includes a metal. In some such embodiments, the metal includes Ni, Ru, Rh, Pd, Ir, Pt, Cr, Mo, or W, or a sulfide, disulfide, halide, or sulfate thereof. In some embodiments, the solution also includes a chelating agent. In some embodiments, the chelating agent includes water, a carbohydrate, an organic acid with more than one coordination group, a lipid, a steroid, an amino acid, a peptide, a phosphate, a nucleotide, a tetrapyrrole, a ferrioxamine, ionophores such as, but not limited to, gramicidin, monensin, valinomycin, phenolics, 2,2′-bipyridyldimercaptopropanol, ethylenedioxydiethylene-dinitrilo-tetraacetic acid, ethylene glycol-bis(2-aminoethyl)-N,N,N′,N″-tetraacetic acid, ionophores-nitrilotriacetic acid, nitrilotriacetate ortho-phenanthroline; salicylic acid; triethanolamine; sodium succinate; sodium acetate; ethylene diamine; ethylenediaminetetraacetic acid; ethylenetriaminepentaacetic acid; and ethylenedinitrilotetraatic acid.

In some embodiments, the solution also includes a buffer. In some such embodiments, the buffer includes, a weak acid and its salt and the weak acid includes succinic acid, formic acid, acetic acid, trichloroacetic acid, hydrofluoric acid, hydrocyanic acid, or hydrogen sulfide.

In some embodiments of the process, the coating is carried out under an inert atmosphere. In other embodiments, the dip-coating is carried out a temperature of from 10° C. to 90° C. In other embodiments, the dip-coating is carried out a pH of 5 to 11.

In another aspect, a process for forming a carbon filament coated glass fiber reinforced polymer composite includes mixing a liquid polymer, a curing agent, and any of the carbon filament coated substrates described above, to form a pre-form mixture. In some embodiments, a ratio of curing agent to liquid polymer is from 0.2:100 to 5:100. In other embodiments, the process also includes molding the pre-form mixture and curing the pre-form mixture. In some such embodiments, the curing is carried out at a temperature and pressure sufficient to cure the polymer. In some embodiments, the liquid polymer includes an orthophthalic polyester resin, an isophthalic polyester resin, a terephthalic polyester resin, a bisphenol A fumarate polyester resin, a chlorendic polyester resin, a dicyclopentadiene polyester resin, a methacrylate vinyl ester resin, a Novolac-modified vinyl ester resin, a diglycidyl ether of bisphenol A epoxy resin, a diglycidyl ether of bisphenol F epoxy resin, a polyglycidyl ether of phenol-formaldehyde Novolac epoxy resin, a polyglycidyl ether of o-cresol-formaldehyde Novolac epoxy resin, N,N,N′,N′-tetraglycidyl methylenedianiline, triglycidyl p-aminophenol epoxy resin, a condensation polyimide resin, or a bis-maleimide cyanate ester resin. In other embodiments, the curing agent includes methyl ethyl ketone peroxide, methyl isobutyl ketone peroxide, acetyl acetone peroxide, cyclohexanone peroxide, tert-butyl peroxyester, benzoyl peroxide, cumene hydroperoxide blend, peroxyester, perketal, calcium oxide, calcium hydroxide, magnesium oxide, magnesium hydroxide, an amine-based curing agent; an anhydride-based curing agent, copper acetylacetonate, or cobalt acetylacetonate.

### BRIEF DESCRIPTIONS OF THE DRAWINGS

FIG. 1 is a schematic of an apparatus for preparing CNF-coated glass fiber, according to one embodiment.

FIG. 2 is an X-ray diffraction (XRD) pattern of as-received and nickel-coated glass fiber, according to the Examples.

FIG. 3 is an XRD pattern of as-received and Ni—P-coated glass fibers at various coating times, according to the Examples.

FIG. 4 is an XRD pattern of as-received and Co-coated glass fibers, according to the Examples.

FIG. 5 is an XRD pattern of Co-coated glass fiber prepared at various temperatures, according to the Examples.

FIG. 6 is an XRD pattern of as-received and Fe-coated glass fibers prepared at various coating times, according to the Examples.

FIG. 7 is an XRD pattern of Ni-coated glass fiber prepared at various pH values, according to the Examples.

FIG. 8 is an XRD pattern of Ni-coated glass fiber prepared at different concentrations of stabilizer, according to the Examples.

FIG. 9 illustrates scanning electron microscope (SEM) images of (a) as-received glass fiber, (b) nickel coated glass fiber and (c) nickel phosphide coated glass fiber, according to various Examples.

FIGS. 10A, B, and C illustrate SEM micrographs of carbon nanocoil coated glass fiber, according to various Examples.

FIGS. 11A, B, and C illustrate SEM micrographs of vertically aligned carbon nanofiber coated glass fiber, according to various Examples.

FIG. 12 is a TEM photograph of a carbon nanofiber, according to various Examples.

FIG. 13A (inner coil diameter) and 13B (outer coil diameter) are histograms of nanocoil diameters, where the average coil diameter is about 250 nm, according to the Examples.

FIG. 14 illustrates the high resolution transmission electron microscopy (HRTEM) images of CNCs, according to the Examples.

FIG. 15: is a Raman spectrum of a CNC prepared at 600° C. and a CNC prepared at 700° C., according to the Examples.

FIGS. 16A, 16B, and 16C are thermogravimetric analysis (TGA) graphs of CNF-coated glass fiber in (A) nitrogen atmosphere, (B) oxygen atmosphere, and (C) air atmosphere.

FIG. 17 are DTA curves of CNF coated glass fiber in (a) oxygen and (b) air atmospheres, according to the Examples.

FIGS. 18A and 18B are SEM images of (A) a single helix twisted carbon nanocoil, and (B) TEM images of single helix twisted carbon nanocoil, according to the Examples.

FIG. 19 is an EDAX analysis of the growth tip of a CNC and an inset SEM image of the CNC, according to the Examples.

FIGS. 20A and 20B illustrate the storage modulus and loss modulus of as-received and CNF coated glass fabrics reinforced epoxy nanocomposites, according to the Examples.

FIG. 21 is a graph of the Tans of as-received and CNF coated glass fibers of reinforced epoxy composites, according to the Examples. As used herein, Tan δ is the ratio of loss modulus to storage modulus.

FIG. 22 is a current-voltage graph of as-received and CNF coated glass fiber composites.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here. The present technology is also illustrated by the examples herein, which should not be construed as limiting in any way.

In one aspect, a carbon filament coated metal oxide substrate is provided, where the carbon filament is arranged angularly to a metal oxide substrate in a dense array. As used herein, the term “angularly” refers to an arrangement where the filament has a proximal end and a distal end is attached to a substrate such that the proximal end is attached to, or in close proximity to, the substrate and the distal end is in a position distal to the substrate, with the surface of the substrate, the proximal end of the filament, and the distal end of the filament defining an angle of greater than zero degrees (i.e. the filament stands on one end on the substrate). The angle may vary from greater than zero degrees to 90°. In some embodiments, the angle is from 45° to 90°. In yet other embodiments, the angle is from 60° to 90° C. In yet further embodiments, a majority of the filaments approximate a 90° angle to the substrate surface. In some embodiments, the filament is a carbon nanocoil (CNC). In other embodiments, the filament is a carbon nanofiber (CNF).

As used herein, a CNF is a cylindrically shaped carbon structure, having a non-hollow core. As used herein, a CNC is a cylindrically shaped tubular structure, made of a network of carbon atoms of a CNT-type structure with a substantially helical conformation. As used herein, a CNT is a cylindrically shaped tubular structure, made of a network of carbon atoms with a substantially linear conformation.

In some embodiments, the metal oxide substrate is a glass fiber. According to various embodiments, the metal oxide substrate includes one or more of boron oxide, aluminum oxide, calcium oxide, magnesium oxide, zinc oxide, titanium oxide, sodium oxide, potassium oxide, lithium oxide, or iron oxide. In some embodiments, the metal oxide substrate is a curved substrate and the carbon filaments are arranged angularly and radially on the curved substrate. Thus, in other embodiments, the carbon filaments, (i.e. CNFs or CNCs) align on the surface of the substrate. In some embodiments, the glass fiber is a glass fabric.

Illustrative glass fibers that may be coated with carbon filaments include, but are not limited to, A-glass (alkali resistant), E-glass (electrical resistant), C-glass (chemical resistant), D-glass (dielectric characteristic), E-CR-glass (corrosion resistant), boron-containing E-glass, boron-free E-glass, R-glass (higher modulus and tensile strength than E-glass), S-glass (higher modulus and tensile strength than E-glass), T-glass (higher modulus and tensile strength than E-glass), Te-glass, silica/quartz glass, low K glass, and hollow glass. In another embodiment, the diameter of glass fiber is from 2 um to 20 μm, from 3 μm to 15 μm, or from 4 μm to 10 μm. In other embodiments, the diameter of the glass fiber is 3.8 μm, 4.5 μm, 5 μm, 6 μm, 7 μm, 9 μm, 10 μm, or 13 μm. The glass fibers may include any of a discontinuous mono-filament, a continuous mono-filament, a continuous flat multi-filament, a continuous twisted multi-filament, or a continuous textured multi-filament. The glass fibers may also be of a variety of weaves, including, but not limited to, two directional fabrics in stacked, stitched or pierced configuration (plain weave, basket weave, twill, 4 end satin, 5 end satin, 8 end satin, leno, mock leno); random fibers; braided yarns; three directional orthogonal or cylindrical weave, or multi-directional weave (four directional to eleven direction).

In another aspect, a process is provided for the manufacture of a carbon filament grown angularly on a metal oxide substrate to form a carbon filament-coated substrate. In some embodiments, the metal oxide substrate is a glass fiber. In other embodiments, the metal oxide substrate has micron-sized dimensions. In some embodiments, the carbon filament is a CNF or CNC. The carbon filaments are grown on the substrate as a result of the decomposition of a hydrocarbon gas in the presence of a catalyst. According to various embodiments, the metal oxide substrate includes boron oxide, aluminum oxide, calcium oxide, magnesium oxide, zinc oxide, titanium oxide, sodium oxide, potassium oxide, lithium oxide, and iron oxide. In some embodiments, the catalyst is a transition metal catalyst.

According to some embodiments, the transition metal catalyst includes at least one of Ni, Ru, Rh, Pd, Ir, Pt, Cr, Mo, or W. In some embodiments the transition metal catalyst includes mixture of at least a first transition metal and a second transition metal. In such embodiments, the first transition metal is at least one of Ni, Ru, Rh, Pd, Ir, or Pt, and the second transition metal is at least one of Cr, Mo, or W. In some embodiments, the transition metal catalyst is mixture of a first transition metal that is at least one of Ni, Ru, Rh, Pd, Ir, or Pt, and Cr. Where the transition metal catalyst is a mixture, the mol ratio of the first transition metal to the second transition metal is from 5 to 1, or from 4 to 1, or from 3 to 1, or from 2 to 1. In some such embodiments, the ratio is 2, or more, to 1.

The catalyst may be initially coated on the substrate. In some embodiments, the catalyst is coated on the substrate by dip coating the substrate in a solution containing the catalyst. In some embodiments, the catalyst is coated on the substrate by spray coating the substrate with a solution containing the catalyst. The conditions for coating may be varied to determine the amount of catalyst that is coated on the substrate. For example, the pH of the solution in which the substrate is dipped in the solution may be varied, as well as the length of time the substrate is contacted with the solution. In some embodiments, the catalyst is coated on the substrate at a temperature of from 10° C. to 90° C. In other embodiments, the solution containing the catalyst is contacted with the substrate for a time period of from 10 seconds to 6 hours. In yet other embodiments, the solution containing the catalyst has a pH of from 5 to 11. In addition to the catalyst, the solution may contain one or more of metal hydrides or hypophosphites of Na, Mg, Al, Zn, or Cu; chelating agents such as water, carbohydrates including polysaccharides, organic acids with more than one coordination group, lipids, steroids, amino acids, peptides, phosphate, nucleotides, tetrapyrrols, ferrioxamines; ionophores such as gramicidin, monensin, valinomycin, phenolics, 2,2′-bipyridyldimercaptopropanol, ethylenedioxydiethylene-dinitrilo-tetraacetic acid, ethylene glycol-bis(2-aminoethyl)-N,N,N′,N″-tetraacetic acid, ionophores-nitrilotriacetic acid, nitrilotriacetate ortho-phenanthroline; salicylic acid; triethanolamine; sodium succinate; sodium acetate; ethylene diamine; ethylenediaminetetraacetic acid; ethylenetriaminepentaacetic acid; and ethylenedinitrilotetraatic acid.

Where the catalyst is coated on the substrate via a dip coating process, it is an electro-less dip coating process. In the electro-less dip coating, a buffer solution used including an acid and its salt. Such acids include, but are not limited to succinic acid, formic acid, acetic acid, tricholoroacetic acid, hydrofluoric acid, hydrocyanic acid, hydrogen sulfide, and water. Such salts may include the sodium or potassium salt of such acids. The dip coating of the catalyst is carried out under an inert atmosphere. The inert atmosphere may be one of N₂, Ar, or He. The electro-less dip coating may be carried out at a temperature of from 10° C. to 90° C. for a time period of 10 seconds to 6 hours to obtain a thickness of catalyst coating of from 50 nm to 200 nm on the substrate. The solution used for dip coating includes an oxidizing agent, a reducing agent, a chelating agent, and buffer. A ratio of oxidizing agent to reducing agent is from 1:100 to 9:100 (by weight). A ratio of chelating agent to buffer is from 1:1 to 1:5; from 1:1 to 1:10; or from 1:0.10 to 1:1 (by weight).

Other techniques for coating the substrate with a catalyst include, but are not limited to, electro plating, dip coating as a sol-gel, spin coating as a sol-gel, radio frequency (RF) sputtering, magnetron sputtering, electron beam evaporation, physical vapor deposition, thermal evaporation, CVD, combustion, co-precipitation, impregnation, Langmuir-Blodgett films, scratching, and others as may be known in the art.

In another aspect, a process is provided for the manufacture of a uniform coating of carbon filaments (i.e. CNCs or CNFs) on a glass fiber substrate via chemical vapor deposition (CVD). The CNCs or CNFs are grown as a result of the decomposition of a hydrocarbon gas in the presence of a transition metal catalyst. Suitable transition metal catalyst(s) are those that include, iron (Fe), cobalt (Co), nickel (Ni), ruthenium (Ru), rhodium (Rh), palladium (Pd), iridium (Ir), platinum (Pt), chromium (Cr), and/or tungsten (W). In some embodiments, the hydrocarbon gas is mixed with one or more of a reducing gas and an inert gas. CNCs may impart electrical and mechanical properties effectively under applied external energies. They have spring elasticity, which upon extension returns to its original length. In addition to this CNCs have outstanding sensor properties and can be used in micro-electro mechanical systems (MEMS), actuators, electromagnet wave absorber, electron emitters, etc. CNCs may also be used as a reinforcing material. Any, or all of the sides of the substrate may be coating using the described process.

The temperature and time period for which the CVD is conducted may be varied depending upon the hydrocarbon gas, the substrate, and the catalyst that is used. Controlling such parameters e.g., catalyst type, catalyst composition, size of catalyst, flow rate of gases during synthesis of carbon, temperature, presence of thiophene, etc., controls the density of the carbon filaments that are deposited on the substrate. It has been observed that the carbon filament-coated glass fiber(s)/fabric is/are more thermally stable if the coating is carried out at high temperature. For example, in a N₂ atmosphere, at the temperature of 450° C., the weight loss of carbon filament-coated glass fiber is found to be ˜3.9% (coating temperature 600° C.). At the same temperature of 450° C., the carbon filament-coated glass fiber (coating temperature 700° C.) shows 0.7% weight loss.

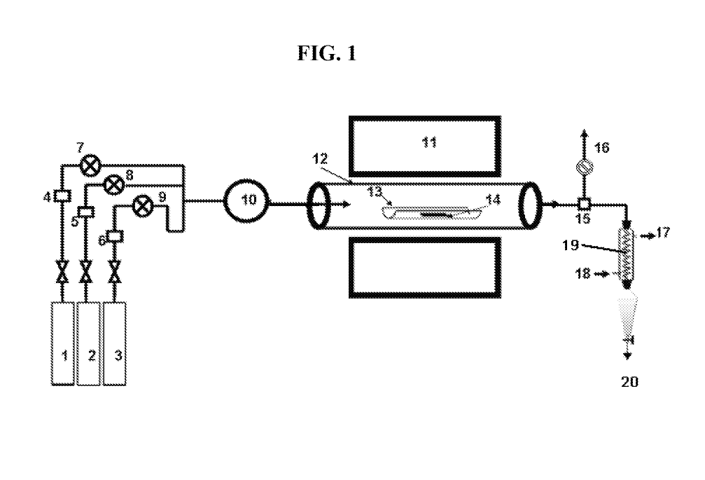

The process for the production of a carbon filament-coated substrate includes coating the catalyst on the substrate, heating the substrate, contacting the hydrocarbon gas with the substrate, and growing the carbon filament on the substrate. By way of illustration of the various steps of the process, an apparatus for carrying out the process is provided in FIG. 1. For the purposes of illustration of the process, the substrate described is referred to as a glass fiber. An early step of the process involves coating of the glass fibers with a catalyst which will promote the formation of the carbon filaments on the glass fibers. The coating of the catalyst on the surface of the glass fiber is conducted over a temperature range of from 10° C. to 90° C. by spray or dip coating of the fibers in a solution of the catalyst. The catalyst-coated glass fibers 14 are then loaded into a vessel 13 for introduction to the reactor 12.

The reactor 12 is contained within a heating source such as a furnace 11. According to various embodiments, the furnace 11 may be single, dual, or triple zone furnace that is configured to maintain the reactor at the desired temperature at which the CNFs will deposit on the glass fibers. An inert gas source 1, hydrocarbon gas source 2, and reducing gas source 3 are employed in the reactor and are controlled by flow controllers 7, 8, 9. Each of the gas sources may optionally be scrubbed by a gas purifying unit 4, 5, 6 to remove impurities such as water. The gases are then introduced to a mixing chamber 10 and are then directed into the reactor 12. At a sufficient temperature the hydrocarbon gas is reduced and the carbon begins to deposit on the glass fibers 14 as carbon filaments. The flow rate of the gas is adjusted such that a sufficient contact time of the gas with the substrate is maintained. After passing through the reactor 12, the gas stream containing unreacted gas, reacted gas, and by-product gas is then directed out through an exit valve 15 and may be condensed by condenser 19, which is cooled by a water stream 18, 17. An outlet 20 for the condensate is provided. The apparatus is also connected to a vacuum 16 such that the apparatus may be evacuated and back-filled with an inert gas to minimize the oxygen content in the apparatus.

During the process, the reactor 12 is maintained at a temperature sufficient to decompose the hydrocarbon gas and deposit the carbon filaments on the substrate. According to some embodiments, the temperature is from 400° C. to 900° C., from 500° C. to 800° C., or from 500° C. to 600° C. In some embodiments, the temperature is from 450° C. to 550° C., or from 490° C. to 510° C. The substrate is contacted with the hydrocarbon gas for a time period sufficient to deposit the desired amount of carbon filaments on the substrate. According to some embodiments, the time period is from 10 seconds to 2 hours; from 10 seconds to 1 hour; or from 1 minute to 1 hour. In some embodiments, the desired amount of the carbon filaments are from 20 nm to 200 nm in diameter and 100 nm to 10 μm in length. The size of the substrate, e.g. the glass fibers, is limited only by the dimensions of the chemical vapor deposition apparatus.

These carbon filaments coated glass fiber may be used to make a variety of composite structures. Potential applications for such materials include: agricultural applications such as containers and enclosures, equipment components, feed troughs, fencing, partitions, flooring, staging, silos and tanks; aerospace and aircraft applications such as containers, control surfaces, gliders and light aircraft construction, internal fittings, partitions and floors, window masks, galley units and trolleys, structural members, satellite components, aerials and associated enclosures, ground support equipment components and enclosures; appliance and business equipment applications such as covers, enclosures, fittings, frameworks and other molded items and assemblies for internal use, and switchgear bodies and associated electrical and insulation components; building and construction applications such as external and internal cladding, permanent and temporary formwork and shuttering, partitions, polymer concrete, pre-fabricated buildings, kiosks, cabins and housing, structural and decorative building elements, bridge elements and sections, quay facings, signposts and street furniture, staging, fencing, and walkways; consumer products components such as domestic and industrial furniture, sanitary ware, sporting goods, caravan components, garden furniture, archery and playground equipment, notice boards, theme park requirements, swimming pools, aqua tubes, diving boards, seating and benches, simulated marble components, skis, and snowboards; corrosion resistant equipment applications such as chemical plant, linings, oil industry components, pipes and ducts, chimneys, grid flooring, staging and walkways, pressure vessels, processing tanks and vessels, fume hoods, scrubbers and cooling tower components, assemblies, and enclosures; national defense applications such as aircraft vehicle, aerospace and satellite components, enclosures and containers, personnel armor, rocketry and ballistic items, shipping and transit containers, and simulators; electrical and electronic applications such as internal and external aerial components and fittings, circuit boards, generation and transmission components, insulators, switch-boxes and cabinets, booms, distribution posts and pylons, telegraph poles, fuse tubes, transformer elements, ladders, and cableways; general engineering and industrial applications such as assemblies and fittings, sundry enclosures, safety helmets, pallets, bins, trays, profiles and medical items, and equipment components; marine applications such as canoes and boats, yachts, lifeboats and rescue vessels, buoys, boat accessories and sub-assemblies, surf and sailboards, window masks and internal moldings and fittings for ferries and cruise liners, work boats and trawlers; transportation applications such as automotive, bus, camper and vehicle components generally, both underbody, engine and body panels, truck, rail and other vehicle components and fittings, land and sea containers, railway track and signaling components, traffic signs, seating, window masks and partition; and water control engineering and sewage applications such as pipes, process and storage vessels, tanks, pump components, staging, walkways, partitions, scrubbers and weirs. Many other applications will be readily envisioned by those of skill in the art.

The CNF or CNC-coated substrates may be characterized through a variety of techniques. Such techniques include, but are not limited to, scanning electron microscopy (SEM), transmission electron microscopy (TEM), atomic force microscopy (AFM), voltage-vs-current characteristics (V-I), thermogravimetric analysis (TGA), X-ray diffraction (XRD) studies, and energy dispersive X-ray analysis (EDAX).

Other techniques for producing the CNF- or CNC-coated substrates include, but are not limited to, electric arc discharge, laser ablation, thermal chemical vapor deposition (CVD), plasma enhanced CVD, microwave CVD, microwave plasma enhanced CVD, radio frequency plasma enhanced CVD, cold plasma enhanced CVD, laser assisted thermal CVD, catalytic CVD, low pressure CVD, aero-gel supported CVD, vapor phase growth CVD, high pressure carbon monoxide disproportionation (HIPCO), water assisted CVD, flame synthesis, hydrothermal synthesis, electrochemical deposition, pyrolysis, and others as may be known in the art.

In another aspect, the CNF or CNC-coated substrate is a glass fiber or glass fabric that is incorporated in a polymer to form a nano-composite. In some embodiments, the polymer is a thermoset polymer. Such nano-composites may also be used in electrical applications as they may be conducting. Such nano-composites may be utilized in structural performance applications, as the CNF-coated glass fibers impart improved properties to the nano-composite, in comparison to glass fiber composites without the carbon filament coating. For example, a 70% improvement in storage modulus is observed for carbon filament-coated glass fiber in polymer composite with respect to the uncoated fiber, and the glass transition temperature of carbon filament-coated glass fiber reinforced polymer composites are shifted to higher temperature with respect to the uncoated glass fiber composite. Such results are an indication that the composites with the carbon filament-coated glass fiber reinforcements may be used in applications that require higher operating temperatures.

Thermoset polymers for use in preparing the nanocomposites, include those that are used in a wide variety of structural and performance applications. Illustrative thermoset polymers include polyesters, epoxies, and polyurethanes. For example, such polymers may include, but are not limited to, orthophthalic polyesters, isophthalic polyesters, terephthalic polyesters, bisphenol A fumarate polyesters, chlorendic polyesters, dicyclopentadiene polyesters, methacrylated vinyl esters, novolac modified vinyl esters, diglycidyl ether of a bisphenol A epoxy, diglycidyl ether of a bisphenol F epoxy, polyglycidyl ether of a phenol-formaldehyde novolac epoxy, polyglycidyl ether of o-cresol-formaldehyde novolac epoxy, N,N,N′,N′ tetraglycidyl methylenedianiline, triglycidyl p-aminophenol epoxy, polyimides (i.e. the condensation product of an aromatic diamine and aromatic dianhydride/diacid), bis-maleimide cyanate esters.

In another embodiment, the thermoset polymer is configured to be cured by a curing agent. In some embodiments, the curing agent may also include a curing accelerator. For example, the curing agent may be a peroxide, such as methyl ethyl ketone peroxide, methyl isobutyl ketone peroxide, acetyl acetone peroxide, cyclohexanone peroxide, tert-butyl peroxyester, benzoyl peroxide paste, cumene hydroperoxide blend, peroxyester, perketal; an oxide or hydroxide of Ca, Mg, or Ba; an amine-based curing agent; an anhydride-based curing agent; or a copper or cobalt acetylacetonate. Where an accelerator is used, the accelerator may be a tertiary amine, a mercaptan, cobalt octanoate, cobalt naphthenate, benzyldimethylamine, 2,4,6-tris(dimethylaminomethyl)phenol, 2-ethyl-4-methylimidazole, or boron-trifluoride-monoethylene-amine).

In another aspect, a process is provided for preparing the nano-composites of the carbon filament-coated substrate and polymer. Generally, the thermoset polymer is provided as a liquid that is mixed with a curing agent. The ratio of thermoset polymer to curing agent may range from 0.2:100 (by weight) to 5:100. The mixing is generally carried out over a temperature range of from 10° C. to 30° C., which is low enough to prevent immediate curing of the polymer. The carbon filament-coated substrate is then placed in a mold, and the mixture of the thermoset polymer and curing agent are added to the mold. The combination of the mold, the carbon filament-coated substrate, and the polymer mixture is known as a pre-form. The pre-form may then be subjected to high pressure at a temperature of from 25° C. to 100° C. to cure the polymer and produce the nano-composite material. The pressure may be added via a hydraulic press and be conducted for from 1 to 24 hours.

Other techniques may also be used to prepare the nano-composites. Such techniques may include, but are not limited to, compression molding, transfer molding, extrusion molding, reactive extrusion molding, co-extrusion molding, injection molding, reaction injection molding, extrusion blow molding, injection blow molding, structural reaction injection molding, structural foam injection molding, structural foam reaction injection molding, sandwich molding, slach-molding, roto-molding, cold press molding, hot press molding, positive vacuum thermoforming molding, negative vacuum thermoforming molding, positive pressure thermoforming molding, negative pressure thermoforming molding, plug-assisted positive vacuum thermoforming molding, plug-assisted negative vacuum thermoforming molding, plug-assisted positive pressure thermoforming molding, plug-assisted negative pressure thermoforming molding, resin transfer molding, pressure-assisted resin transfer molding, vacuum-assisted resin transfer molding, vacuum bag molding, pressure bag molding, autoclave molding, filament winding, or pultrusion.

All publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

The present technology, thus generally described, will be understood more readily by reference to the following examples, which are provided by way of illustration and are not intended to be limiting in any way.

### EXAMPLES

The present technology is further illustrated by the following examples, which should not be construed as limiting in any way.

### Example 1

A horizontal tubular reactor is used to coat CNF on glass fiber(s)/fabric. The reactor has a quartz tube of 1000 mm length with an outer diameter of 105 mm and inner diameter of 100 mm. It is constricted in such a way that a glass fiber(s)/fabric substrate can be readily inserted and removed from the reactor. The reactor is heated in a three zone tubular furnace. A proportional temperature controller controls the furnace temperature in each zone. The temperature is maintained from 500° C. to 900° C. in the mid zone of furnace to facilitate the decomposition of precursor gases. The inlet and outlet temperatures are maintained from 300° C. to 600° C. One or more of N₂, He, Ar, Cl₂, H₂, CH₄, C₂H₆, C₃H₈CO₂, ethylene, and are used as precursor gases. CH₄, C₂H₆, C₃H₃, CO₂, ethylene, acetylene are each carbon source gases, while Cl₂ and H₂ are each reducing gases, and N₂, He, and Ar are carrier gases that also provide for an inert atmosphere inside the reactor.

The glass fiber(s)/fabric is dipped in a bath containing NiSO₄.6H₂O, NaH₂PO₂.H₂O, NH₄Cl, Na₃C₆H₅O₇.2H₂O, and NH₄OH. See Table 2. The catalyst-coated glass fiber(s)/fabric is kept in the middle zone of the reactor. The reactor is then connected to a vacuum line and the pressure is reduced to less than 200 mm Hg. The reactor is then back-filled with an inert gas, and the process is repeated 10 times to reduce the oxygen content inside the reactor. The listings in Tables 3-5 show illustrative conditions for several coating/substrate combinations.

In the next step, the temperature of reactor is increased to 400° C. to 600° C. under an inert atmosphere. The rate of inert gas flow is kept constant at 120 ml/min. After 5 to 10 minutes, the reducing gas is allowed to flow at the rate of 5 to 25 ml/min for 10 to 30 minutes. After 5 to 10 minutes, the temperature is increased to 500-900° C. A carbon-source gas is then introduce at a rate of 10 to 200 ml/min, and the temperature held for 1 to 30 minutes. Prior to introduction to the reactor, the gases are first deoxygenated by passing them through an alkaline pyrogallol solution, concentrated sulfuric acid, calcium chloride, potassium hydroxide, and a silica gel bed. The gases are then mixed before entering into the reactor. Water circulation is carried out at the inlet and exit of the reactor tube to maintain the desired temperature. Water is also used as a coolant in the condenser. Any condensate in the reactor effluent is collected in a liquid collector. During the reaction, CNF grow on the glass fiber(s)/fabric and can be characterized by methods such as XRD, EDAX, SEM, AFM, etc.

TABLE 1
Mechanical Properties of Various Fibers

| | | UTS (Gpa) | | | |
|---|---|---|---|---|---|
| | | (Ultimate | Specific | | Specific |
| | | Tensile | Strength | Modulus | modulus |
| Fiber type | Density | Strength) | (GPa) | (GPa) | (GPa) |
| Carbon fiber | | | | | |
| Type UHM | 2.0 | 2.27 | 1.14 | 483 | 242 |
| Type HM | 1.80 | 2.53 | 1.40 | 345 | 192 |
| Type HT | 1.75 | 3.16 | 1.81 | 206 | 118 |
| E glass | 2.59 | 3.44 | 1.38 | 72 | 29 |
| S glass | 2.49 | 2.60 | 1.06 | 80 | 32 |
| Kevlar 29 | 1.44 | 2.70 | 1.80 | 60 | 42 |
| Kevlar 49 | 1.45 | 2.70 | 1.86 | 130 | 90 |
| Boron (on | 2.50 | 3.75 | 1.50 | 400 | 160 |
| tungsten) | | | | | |
| Asbestos | 3.40 | 3.50 | 1.03 | 190 | 58 |
| (crocidolite) | | | | | |
| Asbestos | 2.50 | 3.11 | 1.24 | 160 | 64 |
| (chrysolite) | | | | | |
| Silicon | 3.50 | 3.50 | 1.00 | 400 | 114 |
| carbide | | | | | |

TABLE 2
Composition for coating of nickel on glass fiber(s)/fabric

| Material | Amount |
|---|---|
| NiSO₄•6H₂O | 30 g/L |
| NaH₂PO₂•H₂O | 12 g/L |
| NH₄Cl | 50 g/L |
| Na₃C₆H₅O₇•2H₂O | 15, 25, 35, 45, and 55 g/L |
| NH₃•H₂O | Excess |
| pH | 6, 7, 8, 9 and 10 |
| Coating temperature | (50, 60, 70, 80, and 90) ± 1° C. |
| Coating times | 0, 5, 10, 15, 25 and 30 mins. |

TABLE 3
Composition for coating of cobalt on glass fiber(s)/fabric

| Material | Amount |
|---|---|
| CoSO₄•7H₂O | 35 g/L |
| NaH₂PO₂•H₂O | 10 g/L |
| NH₄Cl | 50 g/L |
| Na₃C₆H₅O₇•2H₂O | 25 g/L |
| NH₃•H₂O | Alkalinity reserve |
| pH | 8.5 |
| Coating temperature | (60, 70, 80, 90) ± 1° C. |
| Coating time | 5, 10, 15, 20, 25 and 30 mins |

TABLE 4
Composition for coating of iron on glass fiber(s)/fabric

| Material | Amount |
|---|---|
| FeSO₄•7H₂O | 20 g/L |
| NaH₂PO₂•H₂O | 20 g/L |
| Boric acid (H₃BO₃) | 30 g/L |
| Na₃C₆H₅O₇•2H₂O | 60 g/L |
| NH₃•H₂O | Alkalinity reserve |
| pH | 8.5 |
| Coating temperature | (60, 70, 80, 90) ± 1° C. |
| Coating time | 5, 10, 15, 20, 25 and 30 mins |

TABLE 5
Composition for coating of binary transition metal catalysts
i.e. cobalt and nickel on glass fiber(s)/fabric

| Material | Amount |
|---|---|
| NiSO₄•6H₂O | 12 g/L |
| CoSO₄•7H₂O | 22 g/L |
| NaH₂PO₃•H₂O | 25 g/L |
| Na₃C₆H₅O₇•2H₂O | 50 g/L |
| Boric acid (H₃BO₃) | 30 g/L |
| pH at 80° C. | 8.5 |
| (Adjusted using NH₄OH) | |
| Bath Temperature | (60, 70, 80, 90) ± 1° C. |
| Coating time | 5, 10, 15, 20, 25 and 30 mins |

The coating of the catalyst on the substrate may also be carried out by a spraying solution on glass fiber(s)/fabric. Table 6 provides a materials listing for such a solution. After dissolving the metal nitrate, magnesium oxide and citric acid (1:1:4 by weight ratio) in 100 ml de-ionized water, the mixture is stirred at a temperature of 80° C. for 6 hours to obtain a semi-solid mass. The mass is then heated at a temperature of 120° C. for a period of 2 hours. The temperature is then increased to a temperature of from 300° C. to 700° C. for a period of 5 hours in air, followed by cooling to room temperature (25° C.) to obtain a powder of nickel and magnesium oxides.

TABLE 6
Ingredients for NiO—MgO Sol-Gel Spray

| Chemical ingredients | Chemical formula | Concentration (gm/l) |
|---|---|---|
| Nickel nitrate | Ni(NO₃)₂•6H₂O | 0.034 |
| Magnesium oxide | MgO | 0.034 |
| Citric acid | C₆H₈O₇•H₂O | 0.134 |

The coating of the catalyst on the substrate may be also be done by a sol-gel method. Illustrative materials for a NiO—SiO₂ sol-gel are provided in Table 7. The metal nitrate (0.1 M) solution and tetraethyl orthosilicate (TEOS) (4:3 by volume) are mixed in 15 ml ethyl alcohol (total volume 50 ml). The mixture is stirred at room temperature for about 45 minutes to obtain a semi-solid mass which is then heated at a temperature of 100° C. for 24 hours. After this initial heating the mass is further heated in air at a temperature of 300° C. to 600° C. for a period of 5 hours, followed by cooling to room temperature (25° C.) to obtain a powder of nickel and silicon oxides.

TABLE 7
Chemicals used to prepare NiO—SiO2 by Sol-Gel method

| Chemical ingredients | Chemical formula | Amount |
|---|---|---|
| Nickel nitrate aqueous solution | Ni(NO₃)₂•6H₂O | 20 ml of 0.1M |
| Tetraethyl orthosilicate (TEOS) | C₈H₂₀O₄Si | 15 ml |
| Ethyl alcohol | C₂H₅OH | 15 ml |

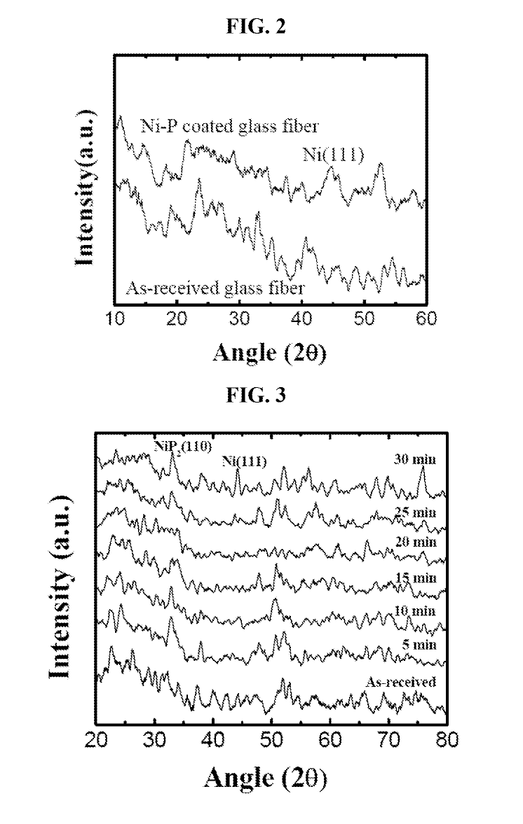

FIG. 2 shows the X-ray diffraction patterns of uncoated glass fiber as well as for a transition metal (e.g. Ni) coated glass fibers. The uncoated glass fiber exhibits no peaks, which indicates an amorphous structure. In the Ni—P coated sample, a peak is observed at 2θ value of 44.5°, which is a characteristic of Ni, as listed in the Joint Committee on Powder Diffraction Standards (JCPDS). The peak at 44.5° corresponds to (111) reflections. It has been shown that when the phosphorus content of the electroless Ni—P coating is increased, the XRD profile becomes less sharp due to the decrease in crystallinity of the coating.

FIG. 3 shows the X-ray diffraction patterns of an uncoated glass fiber as well as the various nickel-phosphorus (Ni—P) coated glass fibers. The uncoated glass fiber exhibits no characteristic peaks at all, indicates an amorphous structure. Where as in Ni—P coated samples, two standard peaks are observed at 2θ values of 31.2 and 44.5°. These are characteristic of NiP₂ and Ni⁰, respectively. The peaks at 31.2 and 44.5° correspond to (110) and (111) reflections, respectively. It has been observed that the peak intensity of the X-ray diffraction patterns increases with an increase of coating time, means coating thickness increases, which is followed by a parabolic rate law. It is also seen that the relative intensity of Ni increases with increasing coating time.

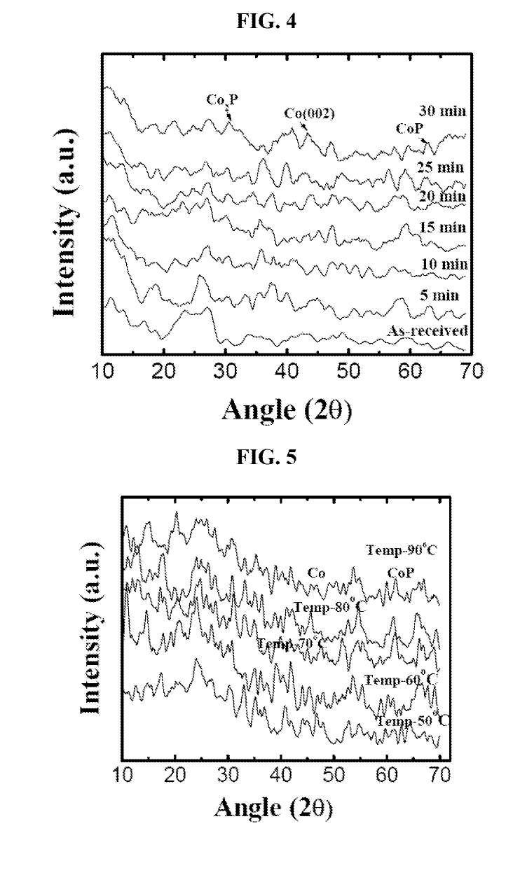

FIG. 4 shows X-ray diffraction patterns of as-received and Co—P coated E-glass fiber/fabric with different coating times. The E-glass fiber/fabric gives a XRD peak at 2θ of 22.5°. The peak is broad and indicates an amorphous nature of the glass fiber. In the Co—P coated samples, a 2θ value of 44.5°, which is characteristic of Co, is observed. This peak corresponds to a Co (002) reflection. The XRD pattern of Co—P coating includes a mixture of amorphous and crystalline phases. Diffraction peaks of Co₂P at 31.2° and CoP at 62.8° (JCPDS number: 32-0306 for Co₂P and 29-0497 for CoP) are also noticed in the XRD pattern. The FIG. 3 does exhibit a noisy background, which is a characteristic of an amorphous structure and glass fiber/fabric. A comparison of the XRD pattern of Co—P coating on glass fiber with time variation reveals that the intensity of Co peak increases with increasing the coating time.

FIG. 5 shows the XRD pattern for the Co coated glass fiber at various bath temperatures. Two main peaks at 2θ of 44.6 and 62.4° corresponding to Co and CoP reflections are observed. When the bath temperature is increased from 50° C. to 80° C., the intensity of the Co (111) peak reflection is decreased, suggesting a decrease in crystallinity with increase in P content of the coating. Co and P content in the deposits increase when the temperature rises from 50° C. to 90° C. Similarly the deposition rate also increases with bath temperature. The flow of the solution towards the glass fiber increases with increasing the temperature of bath due to the convection process. As this decomposition is purely chemical in nature, the reaction product, Co⁰ settles down as fine particles on the substrate, i.e., the glass fibers/fabric.

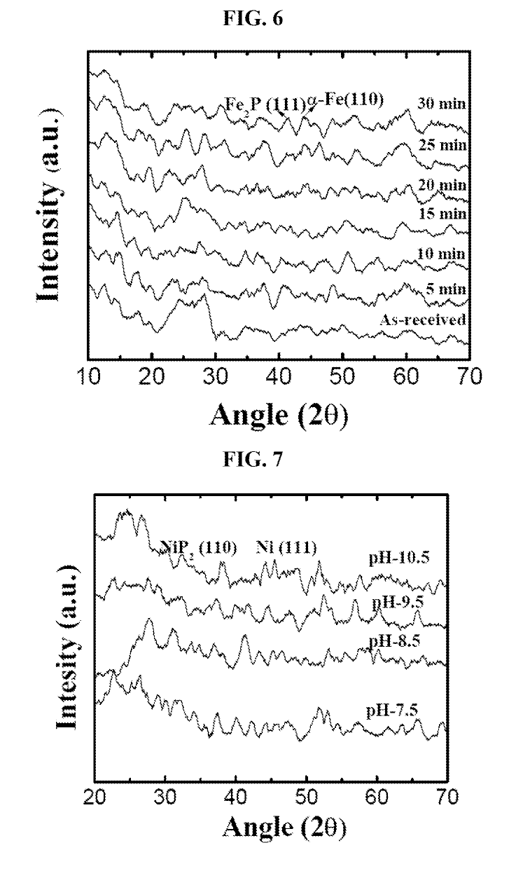

FIG. 6 shows the X-ray diffraction of as-received glass fiber and iron coated glass fiber with function of time. The E-glass fabric gives XRD peak at 2θ=22.5° and the peak is broader indicating amorphous nature of the glass fiber. In Fe—P coated samples, two peaks were observed at 2θ=44.8° and 41.7°, corresponding to (110) and (111) diffraction of α-Fe and Fe₂P, respectively. The crystallization degree of the iron coating was relatively small. As a result, the iron coating is determined to be an amorphous material. In the electroless plating process, an amount of phosphorus atoms were dissolved into the iron structure. With increasing coating time, the peak intensity of the X-ray diffraction patterns of the electroless iron coatings gradually increases. The deposition mechanism of iron is similar to that of nickel and cobalt. The autocatalytic reaction for iron deposition was initiated by catalytic dehydrogenation of the reducing agent.

The nickel-plating using sodium hypophosphite as a reducing agent in a binary alloy of nickel and phosphorus. Most of the properties of coating are structure-dependent and the structure depends on the phosphorus content. As pH was found to control the phosphorus content in the deposits, the pH was studied in the range from 7.5 to 10.5. The higher pH range was used as low pH solution exhibits low deposition rates. Other processing parameters such as temperature, time and stabilizer concentration were kept constant at 80° C., 15 mins and 25 gm/L respectively. According to FIG. 7, it is observed that intensity of nickel peak (44.5°) increases with increasing the pH of solution. Without being bound by theory, it is believed that the increased reducing ability of sodium hypophosphite with increasing the pH, generates more atomic hydrogen and causes more nickel to deposit on the fiber. While with increasing pH the reaction between hypophosphite and atomic hydrogen, which results in the formation of P element, is inhibited. At pH 10.5, the solution is thick due to the precipitation of nickel salt. The baths are usually maintained at the proper pH by addition of ammonium hydroxide to neutralize the acid produced by the deposition reaction. The Ni content in the coating increases with increasing the pH, whereas the P content in the coating decreases. On the other hand, the deposition rate increases with bath pH at first and then after passing through the maximum it decreases with increasing bath pH due to the precipitation of nickel salt. In some embodiments, a pH in the range of 9.0 to 9.5 is used.

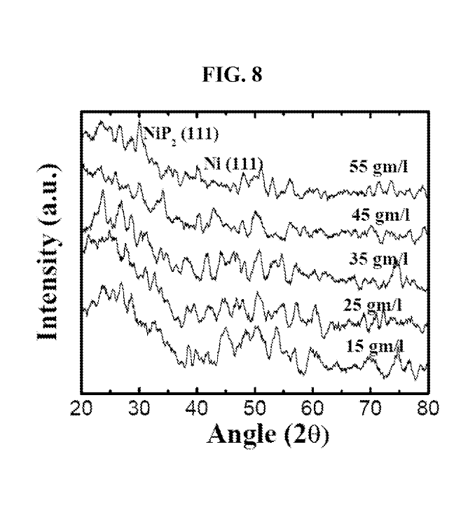

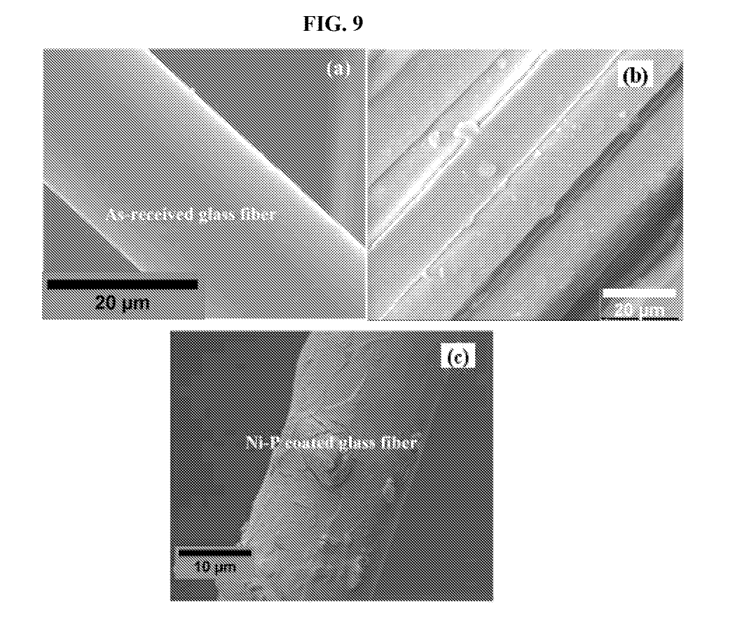

In some examples, sodium citrate was used as a stabilizer, which has a role during deposition of Ni on the glass fiber. It influences the deposition rate of the coating. In order to understand its effect, the coating was carried out with various concentration of stabilizer. It was varied from 15 to 55 gm/L. Other processing parameters such as temperature, time and pH were kept constant at 80° C., 15 min, and 8.5, respectively. The influence of the stabilizer (tri-sodium citrate) concentration on the nickel recovery and deposition rate of the Ni coating is shown in FIG. 8, which shows that the intensity of nickel peaks decreases with increasing the stabilizer content. It is seen that the Ni and P content decreases with increasing the tri-sodium citrate concentration. Below 25 gm/L, the bath decomposes spontaneously; correspondingly a higher amount of nickel and phosphorus content can be seen in the coating. This is possibly due to the formation of nickel phosphide. On the other hand, if the stabilizer content is above 35 gm/L, the deposition rate of nickel decreases due to the decrease in concentrations of free nickel ions. It is observed that the safe range for sodium citrate stabilizer is in the range of 25 to 35 gm/L. Within this range, the Ni and P content in the coating remains same. The deposition rate also decreases with increasing the tri-sodium citrate concentration.

FIG. 9A shows the SEM micrograph of as-received glass fiber. Long cylinders with smooth surfaces and diameter in between 12 to 25 μm are the common morphological characteristics of these fibers. Nickel was coated on the surface of glass fiber, which is used as a catalyst for growing the CNF. FIG. 9B shows the SEM micrograph of nickel coated glass fibers. FIG. 9C shows the SEM micrograph of nickel phosphide coated glass fibers.

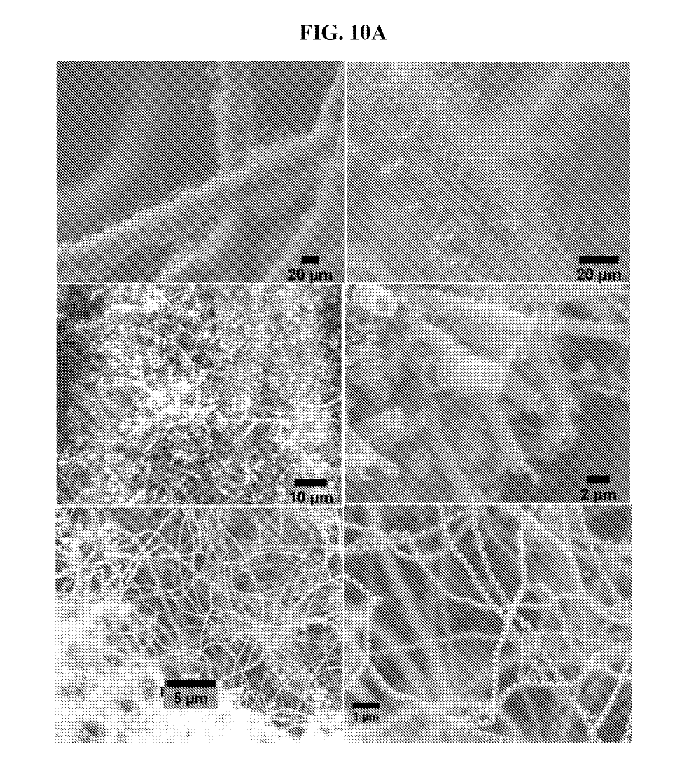

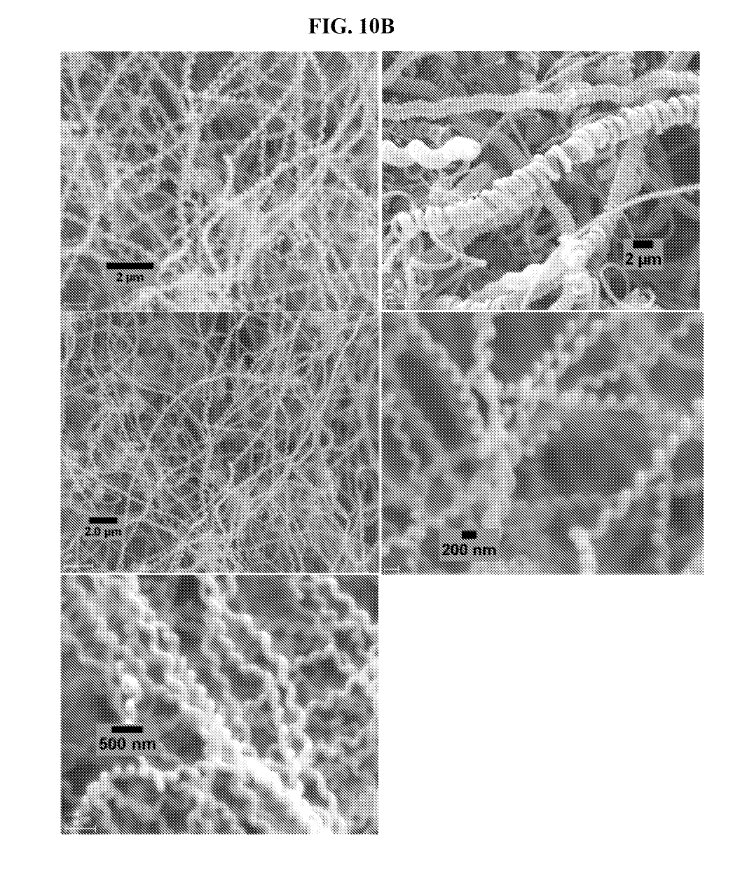

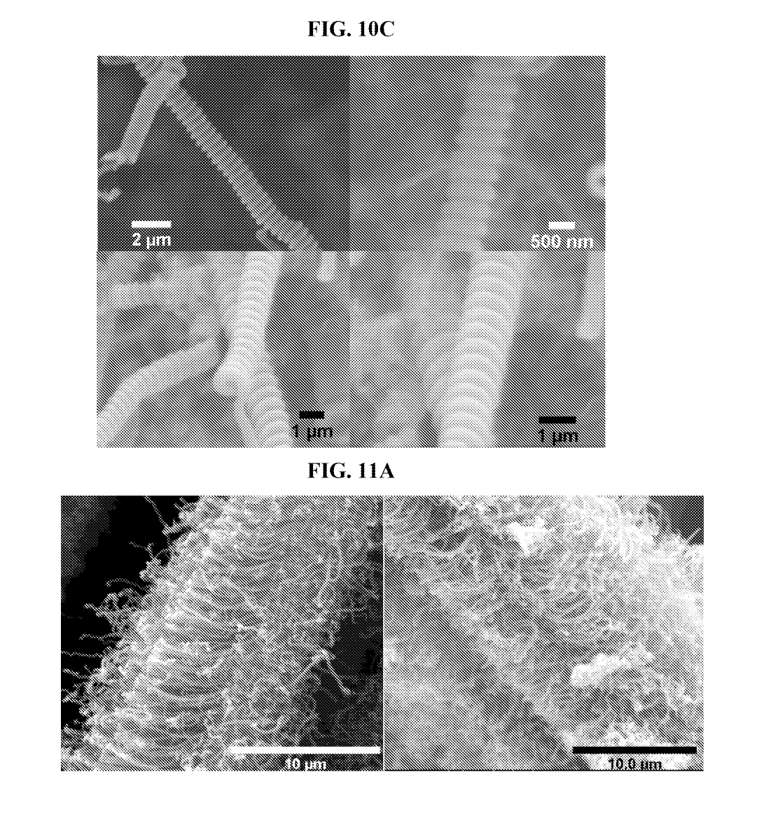

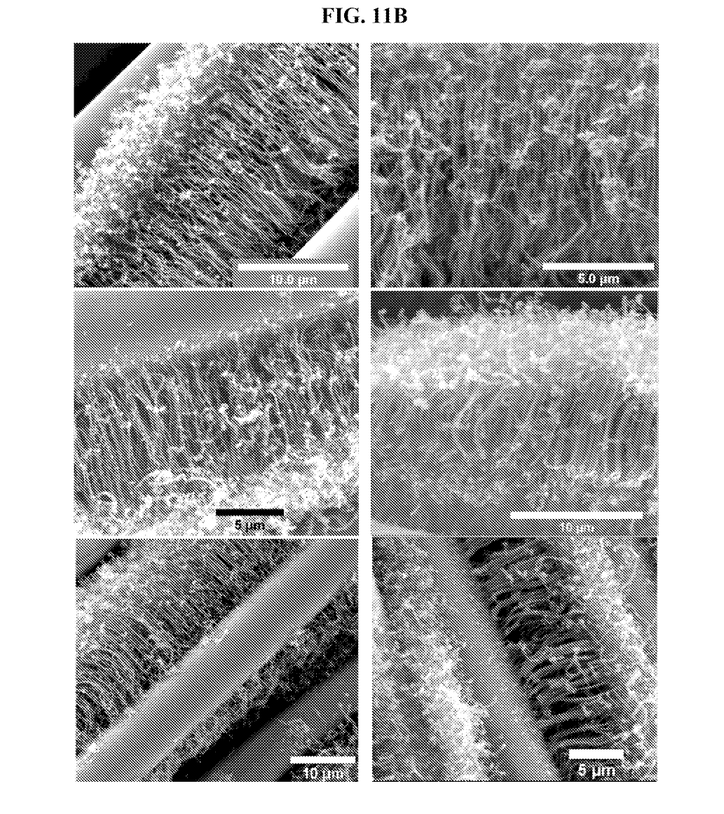

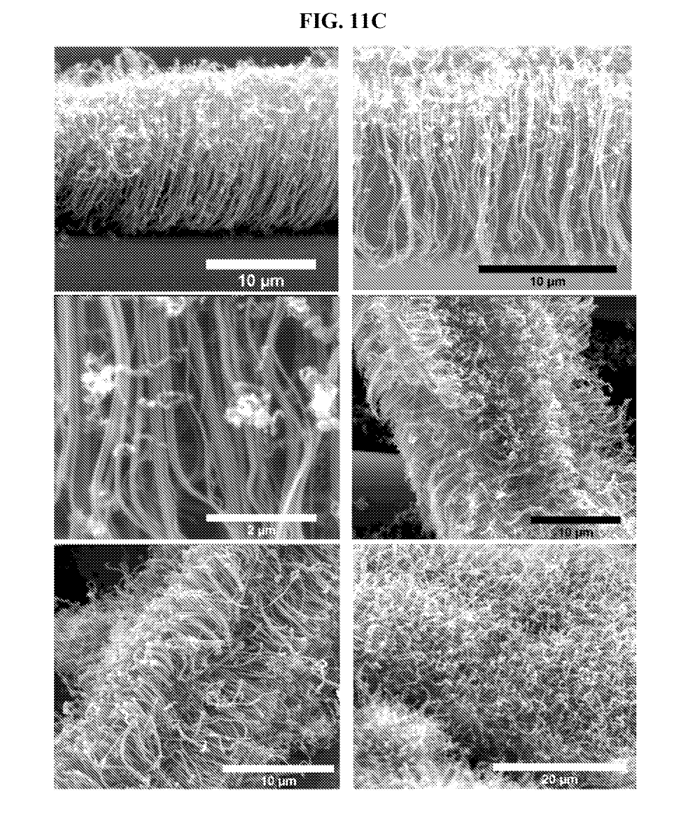

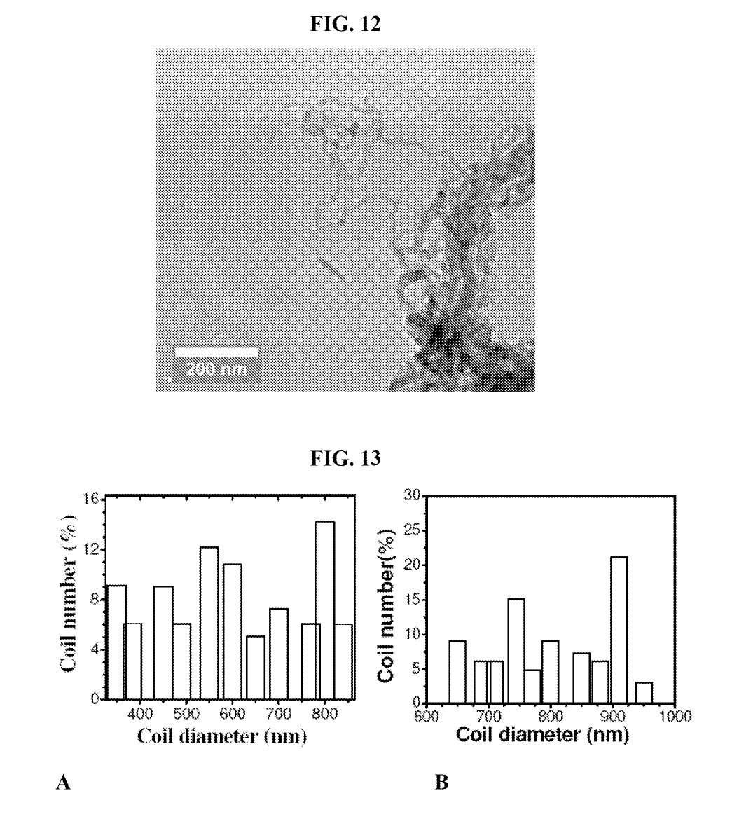

SEM images of CNC-coated glass fiber are shown in FIGS. 10A, B, and C. The yield increases with an increase of temperature from 600 to 700° C. Also, the yield increases in presence of thiophene/sulfuric acid. The histogram in FIG. 13A shows the inner coil diameter, whereas FIG. 13B shows the outer coil diameter, and Table-8 summarizes the dimensions of the nano-coil. SEM images of vertically aligned CNF-coated glass fiber are shown in FIGS. 11A, B, and C. FIG. 12 shows a TEM image of CNFs.

TABLE 8
Synthesis of carbon nano-coils on glass fiber at different processing
temperatures in the presence/absence of H₂SO₄/Thiophene

| | Synthesis Temperature (° C.) | | | |
|---|---|---|---|---|
| | 700 | | 600 | |
| | w/H₂SO₄/ | w/o H₂SO₄/ | w/H₂SO₄/ | w/o H₂SO₄/ |
| Parameters | thiophene | thiophene | thiophene | thiophene |
| Morphology | Single helix nano- | Spring-like nano- | Single helix nano- | Spring-like nano- |
| | coil and Spring- | coil | coil | coil |
| | like nano-coil | | | |
| Coil Length | 30-80 | 30-50 | 8-40 | 9-12 |
| (μm) | | | | |
| Coil gap | 0 to 50 | 100 | 50 | 0 |
| (μm) | | | | |
| Coil | 0 | 384-840 | 0 | 650-950 |
| Diameter | | | | |
| (μm) | | | | |

The results of transmission electron microscopy (TEM) show that the obtained CNF have a length of about 10 μm (FIG. 13). The diameter of the CNFs is in the range of 50-150 nm.

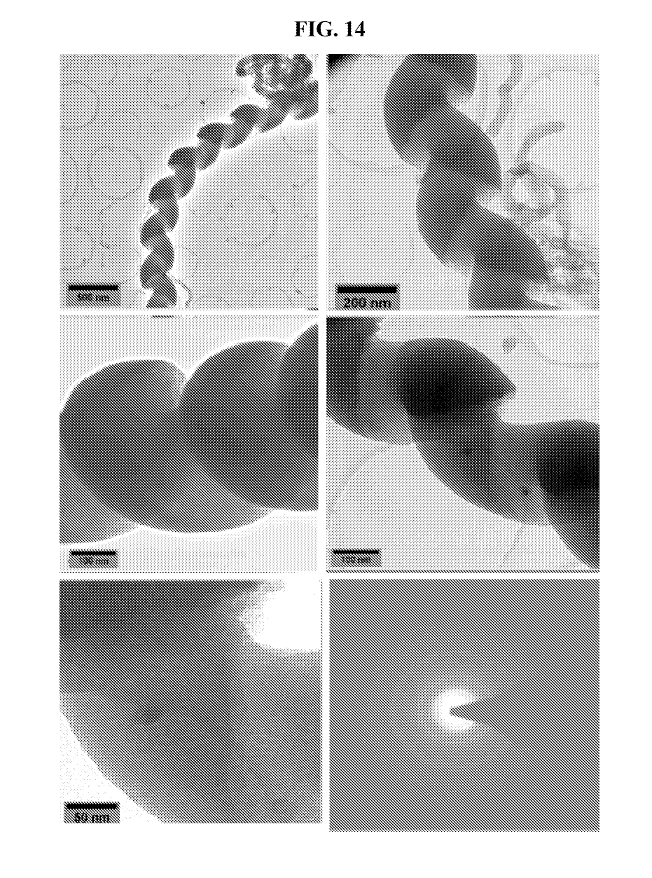

FIG. 14 shows the high resolution transmission electron microscopy (HRTEM) images of a CNC. The CNC has a fine pore through the fiber axis. The external diameter of the coil is 250 nm. It is clear that the coil is formed by a multiple graphite structure. The TEM diffraction patterns show that the CNCs are amorphous.

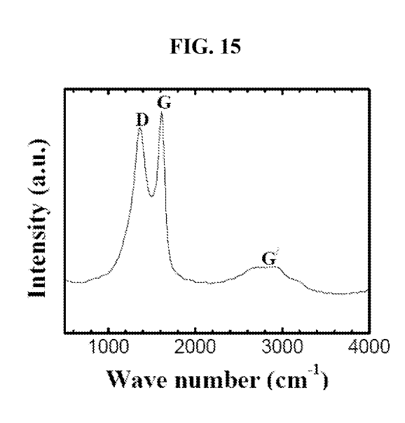

FIG. 15 shows a Raman spectrum of CNC grown on glass fiber. The spectrum shows mainly two Raman bands, one is the D band and other is the G band. The D band indicates disordered features in graphite sheets, and the G band indicates the original graphitic structure. The ratio between the D band and G band is a good indicator of the quality on CNC. The value of ID/IG can express the graphitization of carbon materials. The lower the value, the higher the degree of graphitization. The Raman spectra show two sharp peaks at 1610 cm⁻¹ (G band) and 1370 cm⁻¹ (D band). The G band in the Raman spectra is strong in intensity, whereas D-band is weak due to a lesser amount of amorphous carbon in the CNCs. It has been observed that the value of ID/IG is decreased with increasing processing temperature. The thermogravimetry analysis examines the thermal stability of CNC as a function of temperature.

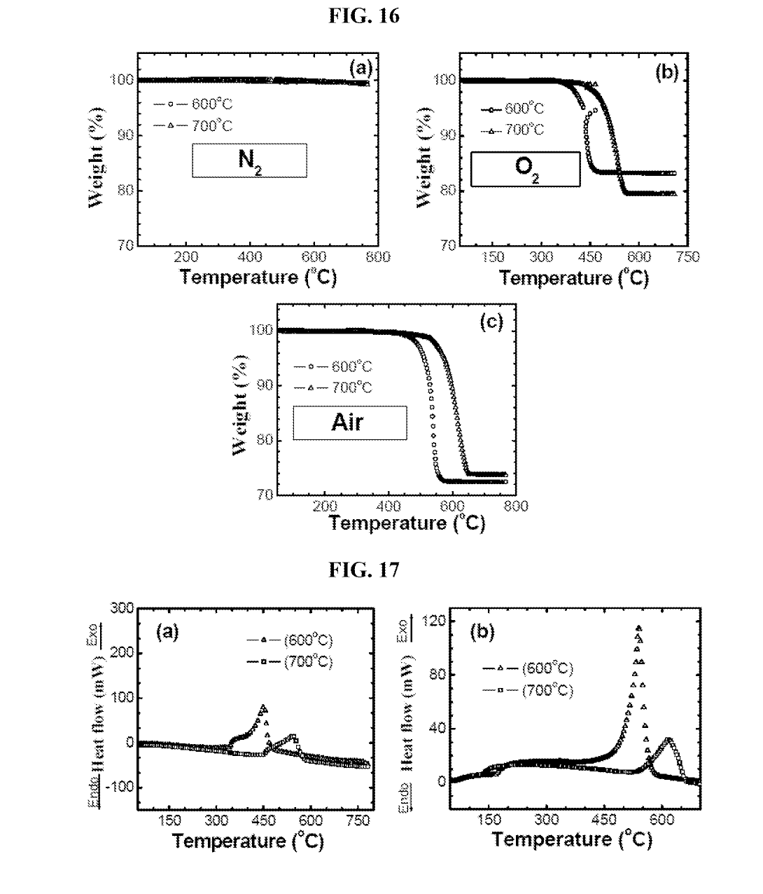

FIGS. 16A, 16B, and 16C show the TGA graphs of CNC-coated glass fibers in nitrogen, oxygen and air atmospheres, respectively. It has been shown that there is no weight loss in the CNC-coated glass fiber in the nitrogen atmosphere, indicating that CNCs are thermally stable up to the temperature of 800° C. in nitrogen atmosphere. In an oxygen atmosphere, a significant weight loss is observed at 400° C., with continued loss as the temperature increases until a stable region is reached at nearly 650° C. The dominant weight loss steps are due to the removal of amorphous carbon materials, and the decomposition of carbon nano-coils, which is taking place in the temperature range of 400 to 550° C. The CNCs grown at 600 and 700° C. start to oxidize at approximately 450 and 500° C., respectively. The respective weight loss takes place over the range of 410 to 450° C., and 500 to 550° C. for the CNCs grown at 600 and 700° C. respectively. The TGA results provide evidence that the degree of crystalline perfection of CNCs becomes better as the growth temperature increases from 600 to 700° C. FIG. 16C, the thermal stability of the CNC is increased due to the presence of air atmosphere.

FIGS. 17A and 17B show the DTA curves of CNC-coated glass fibers in an oxygen atmosphere and in an air atmosphere, respectively. The DTA peak is indicative of the oxidation temperature of CNC. At 600° C., a large spike is apparent due to the sudden loss of mass of CNC, as shown in FIG. 17A. At 700° C., the DTA peak is shifted to higher temperature. It has been confirmed that crystallinity of CNC is increased with increasing CNC processing temperature, which is also confirmed by TGA analysis. In FIG. 17B, the DTA peaks are shifted to higher temperatures due to the presence of air atmosphere. While the CNC growth mechanism is still not thoroughly understood, there suggestions with respect to such growth mechanisms. For example, it is believed that as acetylene is pyrolyzed into carbon atoms and hydrogen molecules, carbon dissolves into the surface of the catalyst particle and forms a carbide phase. When the carbide phase is entirely saturated with carbon, graphite is precipitated from the catalyst particle as a CNC with the same diameter as that of the catalyst particle. The anisotropy of carbon deposition theory is also responsible for the growth of micro/nano coil carbon fiber. The CNC is formed by the rotation of catalyst particle.

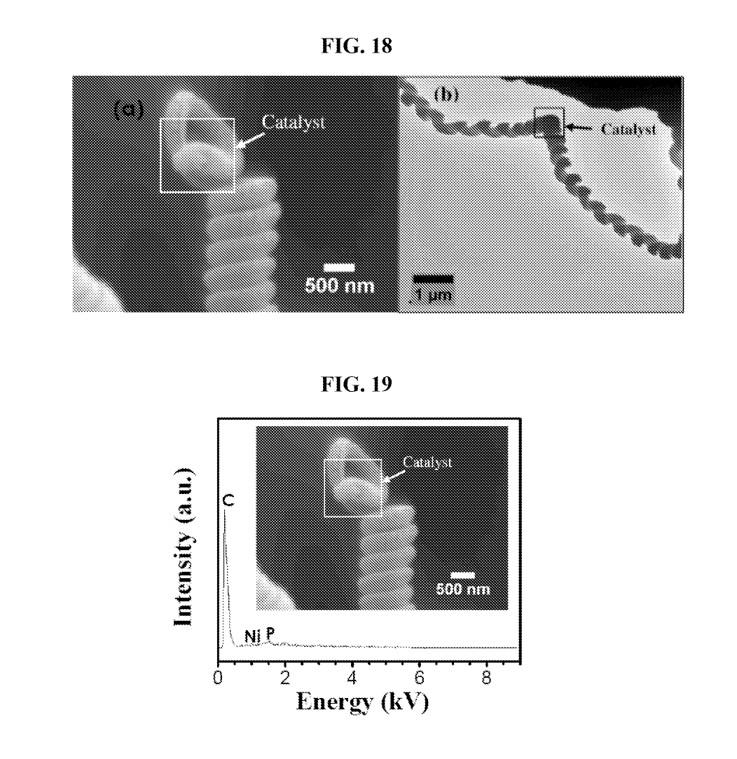

FIG. 18A confirms, through the SEM, that the catalyst is attached to the ends of the CNC. Thus, a tip-growth mechanism exists in this experiment. The catalyst particle is of spherical shape, and two single CNCs grow from a catalyst particle in opposite chirality, left hand coiling chirality and right hand coiling chirality, as shown in FIG. 18B. From the SEM images of CNC, it is observed that the brightened part is catalyst, which is indicated by closed square and arrow sign. See FIG. 19. C, Ni and P are detected in this brightened part by EDAX analysis and the elemental mapping is shown in FIG. 19. The relatively uniform distribution pattern of the Ni and P takes the shape of the catalyst particle. The acetylene is adsorbed in the catalyst, and then pyrolyzed and segregated to form CNC.

### Example 4

Preparation of a nanocomposite. The CNF-coated glass fiber(s)/fabric is/are cut in right shape using the template to make a laminate. The matrix used to prepare the hybrid nanocomposites is unsaturated polyester resin. The weight ratio of polyester resin:catalyst:accelerator is 100:1.2:1.2. Methyl-ethyl ketone peroxide and cobalt octanoate are catalyst and accelerator respectively. Total number of layers used to prepare the hybrid nanocomposite is 3. The composite is prepared by a conventional hand layup technique (vide infra) to prepare a pre-form. The pre-form is then loaded in hydraulic press. The pressure cycle is 5 MPa. The pre-form is allowed to cure at a temperature of 50° C. for 16 hours. The volume fraction of fiber is ˜45%. After curing the hybrid nanocomposites are removed from hydraulic press and is used for the characterization of volume fraction of fibers, storage modulus, loss modulus, and glass transition temperature.

The hand lay-up technique for the fabrication of hybrid nanocomposites includes mixing of a resin/polymer, curing agent (i.e. hardener), and an accelerator (i.e. catalyst) and dipping the fiber(s)/fabric in the mixture and placing it in a mold to provide a shape known as a pre-form. The pre-form is then loaded into a hydraulic press and cured at a pressure of 1 to 10 MPa, and temperature of 2.5-100° C. for a period of 1-24 hours. The polymer to hardener ratio is from 100:0.2 to 100:5. The polymer/hardener to accelerator ratio is from 100:0.2 to 100:5. This differs from the methods described below in which the fabric is placed into a pre-form and then the polymer is added.

### Example 5

The glass fabric is cut into the desired shape using a template from as-received glass fabric, i.e., uncoated glass fabric to make polymer composite. All other conditions are same as mentioned in Example 4 of fabrication of polymer hybrid nanocomposites. This provides for a direct comparison to the coated glass fabrics.

### Example 6

The glass fabric is cut into the desired shape using the template from CNF-coated glass fabric to make polymer hybrid nanocomposites. Polyester resin is replaced by epoxy resin. The weight ratio of epoxy resin:catalyst is 100:2. The catalyst is N,N′-bis(2-aminoethyl)ethane-1,2-diamine. All other conditions are same as mentioned in example 4 of fabrication of polymer hybrid nanocomposites.

### Example 7

The glass fabric is cut into the desired shape using the template from as received glass fabric to make polymer composite. Polyester resin is replaced by epoxy resin. The weight ratio of epoxy resin:catalyst is 100:2. Catalyst is N,N′-bis(2-aminoethyl)ethane-1,2-diamine. All other conditions are same as mentioned in example 4 of fabrication of polymer hybrid nanocomposites. This provide a comparison to Example 6.

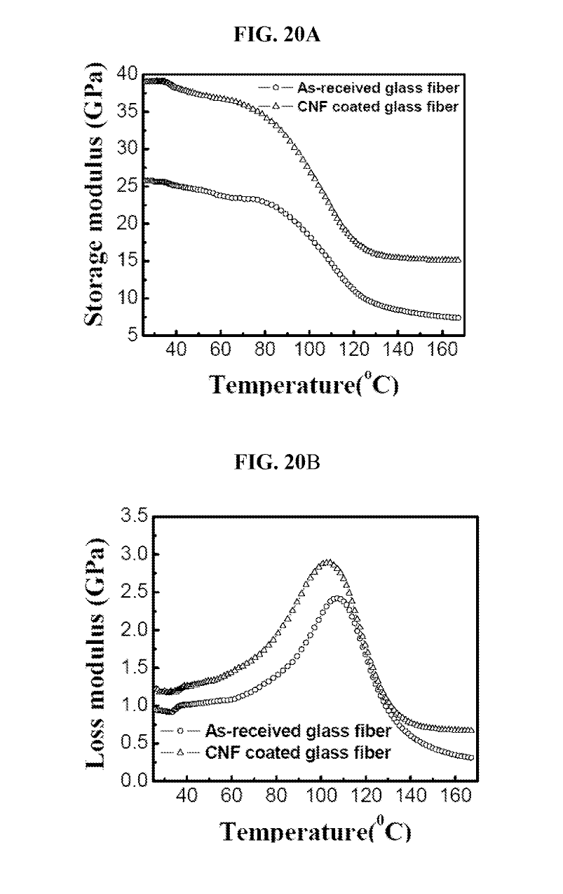

The storage modulus of glass fiber reinforced epoxy composites and CNF-coated glass fiber reinforced epoxy composites is shown in FIG. 20A. Due to the higher modulus of CNFs compared with the glass fiber, CNF coated glass fabrics reinforced epoxy composite shows a higher storage modulus compared with the glass fiber reinforced epoxy composite.

FIG. 20B also shows the loss modulus of glass fiber reinforced epoxy composite and CNF coated glass fiber reinforced epoxy composite. The loss modulus of CNF coated glass fabrics reinforced epoxy composite is higher than that of glass fabrics reinforced epoxy composites due to the inclusion of CNFs.

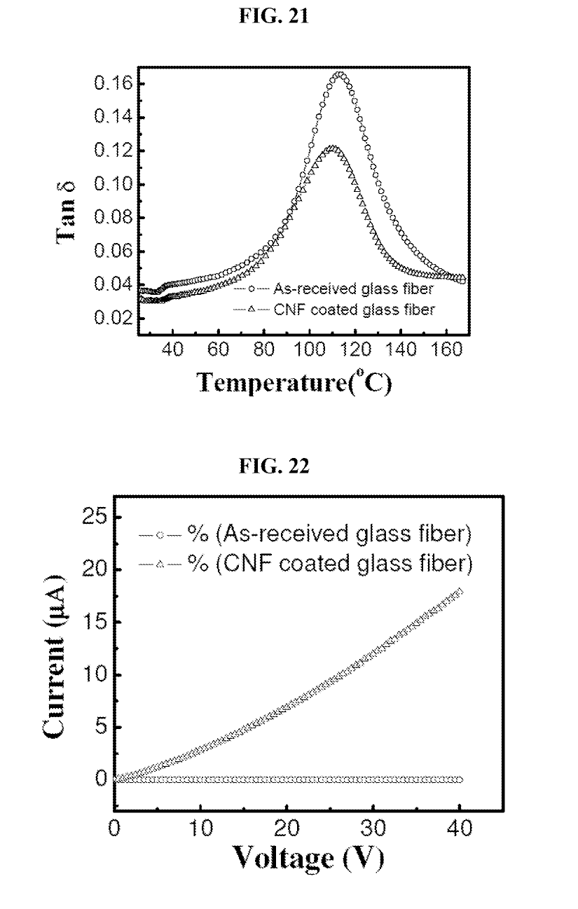

The damping factor (Tan δ) is the ratio of the loss modulus to the storage modulus. FIG. 21 is a graph of the Tan δ curves of glass fabrics reinforced epoxy composite and CNF coated glass fabric-reinforced epoxy composites. It has been observed that the peak intensity of the CNF coated epoxy composite decreases, which reflects the reduction in the damping and due to the presence of CNFs.

FIG. 22 is a current-voltage graph of glass fiber-reinforced epoxy and CNF coated glass fiber reinforced epoxy composites. The glass fiber reinforced composite is an insulator, whereas the CNF coated glass fiber composite is a conductor.

### Equivalents

While certain embodiments have been illustrated and described, it should be understood that changes and modifications can be made therein in accordance with ordinary skill in the art without departing from the technology in its broader aspects as defined in the following claims.

The present disclosure is not to be limited in terms of the particular embodiments described in this application. Many modifications and variations can be made without departing from its spirit and scope, as will be apparent to those skilled in the art. Functionally equivalent methods and compositions within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can of course vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like, include the number recited and refer to ranges which can be subsequently broken down into subranges as discussed above. Finally, as will be understood by one skilled in the art, a range includes each individual member.

Other embodiments are set forth in the following claims.

1. A composition comprising:
at least one glass fiber; and
a plurality of carbon nanocoils radially attached to the glass fiber;
wherein:
each of the carbon nanocoils has a first end in contact with the glass fiber and a second end that is distal to the glass fiber.

2-4. (canceled)

5. A composite comprising:
a polymer;
at least one glass fiber; and
a plurality of carbon nanocoils radially attached to the glass fiber;
wherein:
each of the carbon nanocoils has a first end in contact with the nanocoil and a second end that is distal to the nanocoil; and
the composite is a glass reinforced polymer composite.

6. The composite of claim 5, wherein the polymer is a thermoset polymer.

7. The composition of claim 1, wherein the carbon nanocoil is from 20 nm to 200 nm in width and from 0.5 μm to 10 μm long.

8. The composition of claim 1, wherein the glass fiber has a diameter of from 2 μm to 20 μm.

9. The composition of claim 1, wherein a plurality of the glass and nanocoil fibers are woven into a glass fabric.

10. A process comprising:
coating a catalyst on the surface of a substrate to form a catalyst-coated substrate;
exposing the catalyst-coated substrate to a carbon source gas at a temperature and a time sufficient to decompose the carbon source gas and deposit carbon on the surface of the catalyst-coated substrate as carbon nanocoils.

11. The process of claim 10, wherein the catalyst comprises Ni, Ru, Rh, Pd, Ir, Pt, Cr, Mo, or W.

12. The process of claim 10, wherein the coating comprises dip-coating the substrate in a solution comprising the catalyst.

13. The process of claim 12, wherein the solution further comprises a buffer.

14. The process of claim 10, wherein the carbon source gas comprises CH₄, C₂H₆, C₃H₈CO₂, ethylene, or acetylene.

15. The process of claim 10 further comprising exposing the catalyst-coated substrate and carbon source gas to a reducing gas.

16. A process for forming a carbon filament coated glass fiber reinforced polymer composite comprising mixing a liquid polymer, a curing agent, and a composition according to claim 1 to form a pre-form mixture.

17. The process of claim 16, wherein a ratio of curing agent to liquid polymer is 0.2:100 to 5:100.

18. The process of claim 16 further comprising molding the pre-form mixture and curing the pre-form mixture.

19. The process of claim 18, wherein the curing is carried out at a temperature and pressure sufficient to cure the polymer.

20. The process of claim 11 further comprising exposing the catalyst-coated substrate to H₂SO₄, thiophene, or a mixture thereof.

21. The process of claim 15, wherein the reducing gas is Cl₂ or H₂.

22. The composition of claim 1, wherein the composition is substantially free of amorphous carbon.

23. The composition of claim 1, wherein the composition is free of amorphous carbon.

24. The composite of claim 5, wherein the composite exhibits a storage modulus that is greater than the storage modulus of a comparative composite, wherein the comparative composite is identical to the composite but having at least one glass fiber that does not have carbon nanocoils radially attached to the glass fiber.

25. The composite of claim 5 which is electrically conductive.

26. The composition of claim 1, wherein adjacent nanocoils of the plurality of nanocoils are substantially aligned.
